(19) United States
(12) Patent Application Publication
(10) Pub. No.: US 2008/0094056 A1
(43) Pub. Date: Apr. 24, 2008

(54) Device and method for detecting battery voltage level

(75) Inventor: Yu Lin Huang, Jhonghe City (TW)

Correspondence Address: TROXELL LAW OFFICE PLLC;SUITE 1404, 5205 LEESBURG PIKE, FALLS CHURCH, VA, 22041, US

(73) Assignee: Premier Image Technology Corp.

(21) Appl. No.: 11/583,973

(22) Filed: Oct. 20, 2006

(51) Int. Cl. G01R 19/25

(52) U.S. Cl. 324/120

(57) ABSTRACT

A device and an associated method for detecting a voltage level of a battery are disclosed. The device employs an analog-to-digital converter or digital-to-analog converter to accurately detecting the voltage level. In one embodiment, the device includes a digital-to-analog converter, a comparison circuit, and a microprocessor. The digital-to-analog circuit outputs a plurality of reference levels according to a setting signal. The comparison circuit is for comparing the output voltage of the battery with the reference levels and outputting a comparison signal. The microprocessor then determines the voltage level of the battery according to the comparison signal.

### BACKGROUND OF INVENTION

1. Field of the Invention

The present invention relates to the detection of battery voltage levels, and more particularly to a device and an associated method for detecting the battery voltage level by using an analog-to-digital converter or digital-to-analog converter.

2. Description of the Prior Art

The battery is an indispensable component of portable electronic devices, such as digital camera, notebook PC and mobile phone. The output voltage level of the battery would drop as the battery ages. In light that electronic components might be damaged by the insufficient voltage provided by the battery, portable electronic devices are typically designed with a protective mechanism (e.g. automatic shutdown), which is activated when battery voltage falls below a minimum allowable level, to prevent damage to the electronic components.

FIG. 1 shows the diagram of a conventional battery voltage detection circuit, which generates three reference levels V₁, V₂, and V₃ by means of a voltage source V_{dd} and voltage dividing resistors R₁, R₂ and R₃, and thus creates four level intervals, i.e. larger than V₁, V₁˜V₂, V₂˜V₃, and smaller than V₃. Then three comparators 11, 12 and 13 are used to compare the output voltage V_{BAT} of the battery with the three reference levels, so as to find which level interval the current output voltage level lies in. FIG. 1 gives the example of three reference levels. In fact, more voltage dividing resistors and comparators can be used to generate more reference levels and level intervals.

However, the circuit in FIG. 1 needs to use multiple comparators and voltage dividing resistors which jacks up the cost of hardware. In addition, to produce precise reference levels, the voltage dividing resistances must be under precise control, which is difficult in practice since the resistance value is subject to the influence of process, temperature, and other factors. Thus the circuit in FIG. 1 is hardly able to precisely detect the battery voltage level, and also affects its ability to make a correct judgment as to whether the battery voltage has fallen below the minimum allowable level such that early or late activation of the protective mechanism might occur. As a result, the performance of the portable electronic device is affected or its components might be damaged. In addition, in the circuit of FIG. 1, the adjustment of reference levels can only be achieved by adjusting the hardware circuit (e.g. changing the voltage dividing resistance), which is quite an inconvenience in practice.

### SUMMARY OF INVENTION

It is therefore one object of the present invention to provide a device and an associated method for detecting battery voltage levels, which can accurately detect the battery voltage level and thus avoid misjudgment by the protective mechanism of the electronic device.

Another object of the present invention is to provide a device and an associated method for detecting battery voltage levels, which can make use of an analog-to-digital (A/D) converter or digital-to-analog (D/A) converter included in the digital signal processor of the electronic device to perform detection, thereby saving the cost of hardware.

Another object of the present invention is to provide a device and an associated method for detecting battery voltage levels, which allows flexible setting of voltage reference levels for detection without need to adjust hardware circuit.

According to one aspect of this invention, a device for detecting a voltage level of a battery is provided. The device comprises: an A/D converter for outputting a digital signal corresponding to an output voltage of the battery; and a microprocessor, coupled to the A/D converter, for determining the voltage level of the battery according to the digital signal.

According to another aspect of this invention, a device for detecting a voltage level of a battery is provided. The device comprises: a D/A converter for outputting a plurality of reference levels according to a setting signal; a comparison circuit, coupled to the battery and the D/A converter, for comparing an output voltage of the battery with the reference levels and outputting a comparison signal; and a microprocessor, coupled to the comparison circuit, for determining a voltage level of the battery according to the comparison signal.

According to another aspect of this invention, a method for detecting a voltage level of a battery is provided. The method comprises the steps of: outputting a plurality of reference levels according to a setting signal; comparing an output voltage of the battery with the reference levels to output a comparison signal; and determining the voltage level of the battery according to the comparison signal.

### BRIEF DESCRIPTION OF THE DRAWINGS

FIG. 1 is the diagram of a conventional battery voltage detection circuit.

FIG. 2A is the diagram of a battery voltage level detection device according to a first embodiment of the invention.

FIG. 2B is the diagram of a battery voltage level detection device according to a second embodiment of the invention.

FIG. 3 is the diagram of a battery voltage level detection device according to a third embodiment of the invention.

FIG. 4 is a flow chart showing the method for detecting a battery voltage level according to a fourth embodiment of the invention.

FIG. 5 is a flow chart showing the method for detecting a battery voltage level according to a fifth embodiment of the invention.

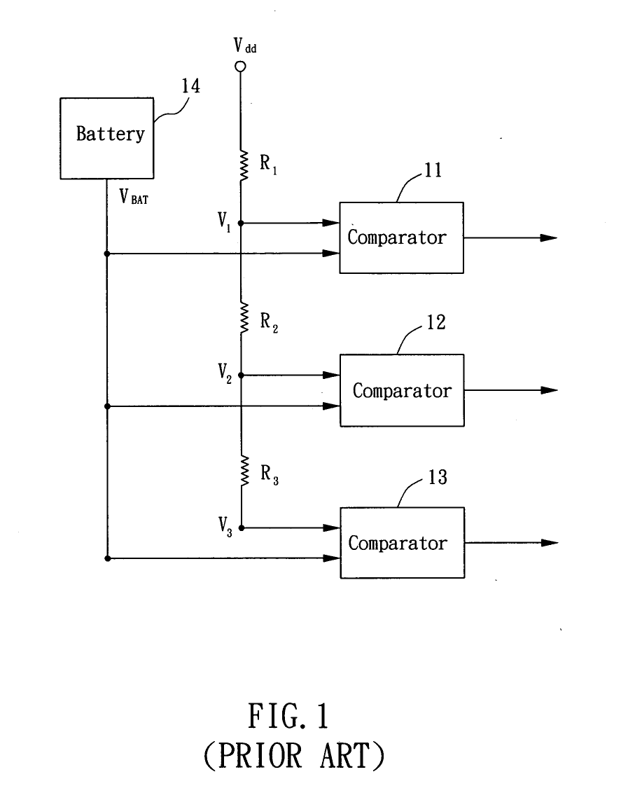

### DETAILED DESCRIPTION

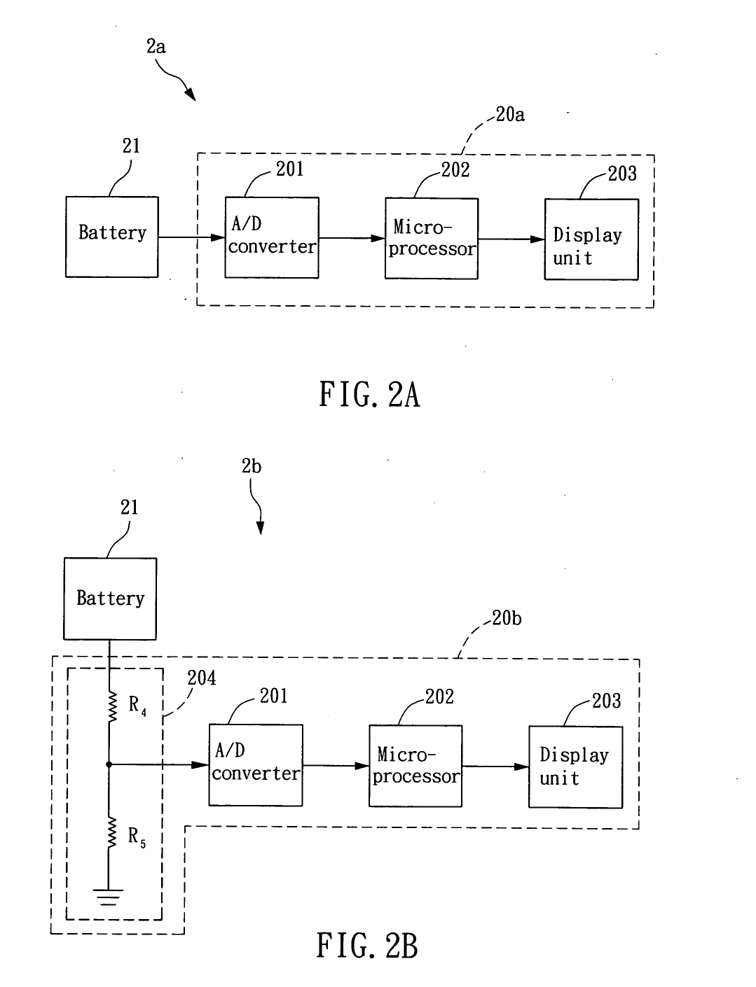

FIG. 2A is the diagram of a battery voltage level detection device according to a first embodiment of the invention. The detection device 20a is included in an electronic device 2a and comprises an analog-to-digital (A/D) converter 201, a microprocessor 202, and a display unit 203. The A/D converter 201 is coupled to a battery 21 of the electronic device 2a and converts an analog voltage signal output by the battery 21 to a corresponding digital signal. The microprocessor 202, coupled to the A/D converter 201, determines the current voltage level of the battery 21 according to the digital signal, and outputs a corresponding level signal to the display unit 203. The microprocessor 202 may determine the voltage level of the battery 21 by executing a firmware program. Moreover, if the microprocessor 202 determines that the voltage level is below a threshold, it will activate a protective process of the electronic device 2a, such as automatic shutdown or entering a standby mode. The threshold is the lowest allowable value for the voltage level of battery 21. If the microprocessor 202 determines that the current output level of battery 21 has fallen below this value, the protective process is activated to protect the internal components of the electronic device 2a from damage. The display 203 unit displays the current voltage level of battery 21 according to the level signal output by microprocessor 202. For example, if the battery voltage level is represented by a level indicator with a scale, then the level signal can represent the reading on the scale corresponding to the current battery voltage level. Then, the display unit 203 will display the level indicator on a display screen according to the reading.

The operation of the detection device 20a in FIG. 2A is illustrated by an example below. Assuming the A/D converter 201 is 8 bits and its input limit is 3.3V. When the output voltage V_{BAT} of battery 21 is 3V, A/D converter 201 will convert V_{BAT} into a binary value 11101000 (i.e. 3*2⁸/3.3 ≈232 (decimal)=11101000 (binary)). Next, microprocessor 202 will execute a firmware program to determine the voltage level according to the binary value. For example, the firmware program first sets the corresponding relationship of the binary value and the reading on the scale of the level indicator mentioned above, and sets a binary value as the threshold. As such, the microprocessor 202 can output the level signal (which represents the reading on the scale) corresponding to the binary value generated by the A/D converter 201, and compare the binary value with the threshold to determine whether to activate the protective process.

FIG. 2B is the diagram of a battery voltage level detection device according to a second embodiment of the invention. In FIG. 2B, detection device 20b is included in an electronic device 2b. In comparison with detection device 20a in FIG. 2A, the detection device 20b contains in addition a voltage dividing circuit 204 which is coupled between battery 21 and A/D converter 201 and outputs a voltage dividing signal to the A/D converter 201 according to the output voltage of battery 21. The A/D converter 201 then converts the voltage dividing signal into a corresponding digital signal. The remaining operation in FIG. 2B is similar to that in FIG. 2A and will not be elaborated here. The addition of the voltage dividing circuit 204 in FIG. 2B takes into consideration that the output voltage of battery 21 might exceed the acceptable limit of A/D converter 201 under certain circumstances. The voltage dividing circuit 204 can lower the voltage level inputted into the A/D converter 201 to circumvent the aforesaid problem. As shown in FIG. 2B, the voltage dividing circuit 204 includes resisters R₄ and R₅. The voltage dividing signal output by the circuit 204 is then the product of the output voltage of battery 21 and R₅/(R₄+R₅).

In a preferred embodiment, electronic devices 2a and 2b comprise a digital signal processor (not shown in the figures) which contains the A/D converter 201 and the microprocessor 202. In other words, detection devices 20a and 20b use the A/D converter and microprocessor inherent in the digital signal processor to carry out detection. As such, less electrical components are used, thereby saving the cost of hardware.

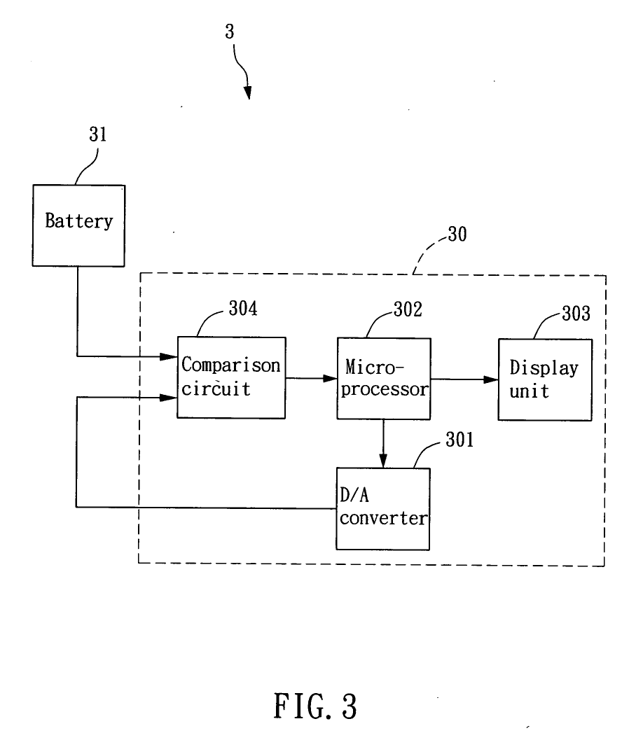

FIG. 3 is the diagram of a battery voltage level detection device according to a third embodiment of the invention. In FIG. 3, the detection device 30 is included in an electronic device 3 and comprises a digital-to-analog (D/A) converter 301, a microprocessor 302, a display unit 303, and a comparison circuit 304. The D/A converter 301 outputs in sequence a plurality of reference levels to comparison circuit 304 according to a setting signal output by microprocessor 302. The reference levels create a plurality of level intervals. For example, if those reference levels are 2.0V, 2.3V and 2.5V, four level intervals are created, i.e. smaller than 2.0V, 2.0˜2.3V, 2.3˜2.5V, and larger than 2.5V. Comparison circuit 304 will compare the output voltage of a battery 31 in electronic device 3 with those reference levels, and output a comparison signal accordingly. The microprocessor 302 can determine which level interval the current voltage level of battery 31 is in according to the level of the comparison signal, and output a corresponding level signal to display unit 303. In the third embodiment, the microprocessor 302 makes the above judgment by executing a firmware program. Microprocessor 302 can also generate the aforesaid setting signal by executing a firmware program to set the reference level. That is, the reference level can be adjusted by the setting signal generated by the microprocessor 302 via the execution of a firmware program. As such, the reference levels can be set directly by using a firmware without the adjustment of hardware circuit.

Moreover, one of the reference levels output by D/A converter 301 can be selected as a threshold value. The significance of the threshold is similar to that described in the first embodiment. If the microprocessor 302 determines according to the comparison signal output by the comparison circuit 304 that the current voltage level of battery 31 is below the threshold, it will activate a protective process of electronic device 3, such as automatic shutdown or entering a standby mode. Besides, the display unit 303 displays the current voltage level of battery 31 according to the level signal output by the microprocessor 302. For example, in the case of three reference levels 2.0V, 2.3V and 2.5V, four level intervals are created (i.e. smaller than 2.0V, 2.0˜2.3V, 2.3˜2.5V, and larger than 2.5V). If the level interval is represented by a level indicator with a scale, then the level signal can represent the reading on the scale corresponding to the level interval where the current battery voltage level lies. Then, the display unit 303 will display the level indicator on a display screen according to the reading. For instance, if the current output voltage is 2.4V, the level of output voltage can be known as between 2.3˜2.5V according to comparison circuit 304 and then is shown by display unit 303.

In a preferred embodiment, electronic device 3 comprises a digital signal processor (not shown in the figure), which contains the D/A converter 301 and the microprocessor 302. In other words, detection device 30 uses the D/A converter and microprocessor inherent in the digital signal processor to carry out detection. As such, less electrical components are used, thereby saving the cost of hardware.

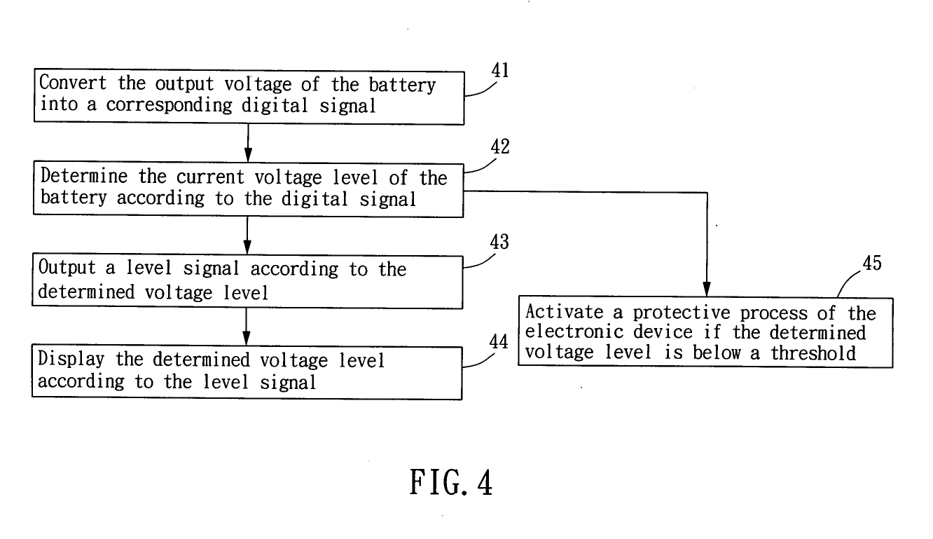

FIG. 4 is a flow chart showing the method for detecting a battery voltage level according to a fourth embodiment of the invention. This detection method is applied to an electronic device, which comprises a battery and a digital signal processor. The digital signal processor further comprises an A/D converter and a microprocessor. As shown in FIG. 4, the detection method includes the following steps:

Step 41: Convert the output voltage of the battery into a corresponding digital signal;

Step 42: Determine the current voltage level of the battery according to the digital signal;

Step 43: Output a level signal according to the determined voltage level;

Step 44: Display the determined voltage level according to the level signal; and

Step 45: Activate a protective process of the electronic device if the determined voltage level is below a threshold.

Step 41 is carried out by the A/D converter. Step 42 is performed by the microprocessor via the execution of a firmware program. In step 44, the voltage level can be displayed by a level indicator with a scale. In step 45, the protective process can be an automatic shutdown procedure to protect the internal components of the electronic device from damage.

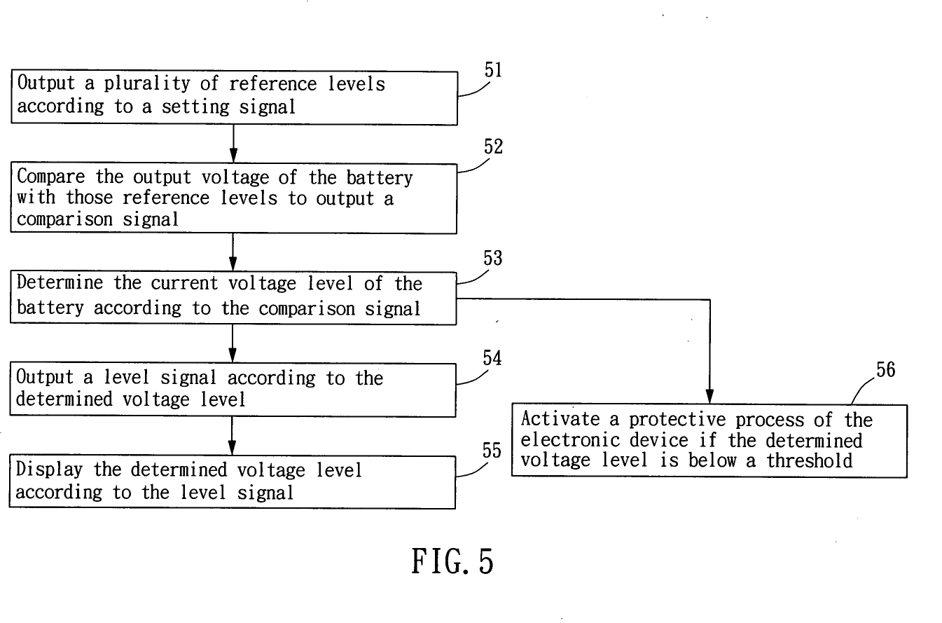

FIG. 5 is a flow chart showing the method for detecting a battery voltage level according to a fifth embodiment of the invention. This detection method is applied to an electronic device, which comprises a battery and a digital signal processor. The digital signal processor further comprises a D/A converter and a microprocessor. As shown in FIG. 5, the detection method includes the following steps:

Step 51: Output a plurality of reference levels according to a setting signal;

Step 52: Compare the output voltage of the battery with those reference levels to output a comparison signal;

Step 53: Determine the current voltage level of the battery according to the comparison signal;

Step 54: Output a level signal according to the determined voltage level;

Step 55: Display the determined voltage level according to the level signal; and

Step 56: Activate a protective process of the electronic device if the determined voltage level is below a threshold.

Step 51 is carried out by the D/A converter. Step 53 is performed by the microprocessor via the execution of a firmware program. In step 51, the setting signal is produced by the microprocessor via the execution of a firmware program for flexible setting or adjustment of reference levels. In step 55, the voltage level can be displayed by a level indicator with a scale. In step 56, the protective process can be an automatic shutdown procedure to protect the internal components of the electronic device from damage.

While the present invention has been shown and described with reference to the preferred embodiments thereof and in terms of the illustrative drawings, it should not be considered as limited thereby. Various possible modifications and alterations could be conceived of by one skilled in the art for the form and the content of any particular embodiment, without departing from the scope and the spirit of the present invention.

What is claimed is:

1. A device for detecting a voltage level of a battery comprising:
an analog-to-digital (A/D) converter for outputting a digital signal corresponding to an output voltage of the battery; and
a microprocessor, coupled to the A/D converter, for determining the voltage level of the battery according to the digital signal.

2. The device according to claim 1, wherein the battery is used by an electronic device comprising a digital signal processor, and the digital signal processor comprises the A/D converter and the microprocessor.

3. The device according to claim 1, wherein the microprocessor determines the voltage level of the battery by executing a firmware program.

4. The device according to claim 1, further comprising:
a display unit, coupled to the microprocessor, for displaying the voltage level of the battery according to a level signal corresponding to the voltage level, wherein the level signal is outputted by the microprocessor.

5. The device according to claim 4, wherein the display unit displays the voltage level of the battery by a level indicator.

6. The device according to claim 1, wherein the microprocessor activates a protective process of the electronic device when the microprocessor determines that the voltage level of the battery is below a threshold.

7. The device according to claim 6, wherein the protective process is an automatic shutdown procedure or entering a standby mode.

8. The device according to claim 1, further comprising:
a voltage dividing circuit, coupled between the battery and the A/D converter, for outputting a voltage dividing signal to the A/D converter according to the output voltage of the battery;
wherein the A/D converter generates the digital signal according to the voltage dividing signal.

9. A device for detecting a voltage level of a battery comprising:
a digital-to-analog (D/A) converter for outputting a plurality of reference levels according to a setting signal;
a comparison circuit, coupled to the battery and the D/A converter, for comparing an output voltage of the battery with the reference levels and outputting a comparison signal; and
a microprocessor, coupled to the comparison circuit, for determining a voltage level of the battery according to the comparison signal.

10. The device according to claim 9, wherein the battery is used by an electronic device comprising a digital signal processor, and the digital signal processor comprises the D/A converter and the microprocessor.

11. The device according to claim 9, wherein the microprocessor determines the voltage level of the battery by executing a firmware program.

12. The device according to claim 9, wherein the microprocessor generates the setting signal to the D/A converter.

13. The device according to claim 12, wherein the microprocessor generates the setting signal by executing a firmware program.

14. The device according to claim 9, further comprising:
a display unit, coupled to the microprocessor, for displaying the voltage level of the battery according to a level signal corresponding to the voltage level, wherein the level signal is outputted by the microprocessor.

15. The device according to claim 14, wherein the display unit displays the voltage level of the battery by a level indicator.

16. The device according to claim 9, wherein the microprocessor activates a protective process of the electronic device when the microprocessor determines that the voltage level of the battery is below a threshold.

17. The device according to claim 16, wherein the protective process is an automatic shutdown procedure or entering a standby mode.

18. A method for detecting a voltage level of a battery comprising the steps of:
outputting a plurality of reference levels according to a setting signal;
comparing an output voltage of the battery with the reference levels to output a comparison signal; and
determining the voltage level of the battery according to the comparison signal.

19. The method according to claim 18, wherein the battery is used by an electronic device comprising a digital signal processor, the step of outputting the reference levels is carried out by a digital-to-analog converter included in the digital signal processor, and the determining step is carried out by a microprocessor included in the digital signal processor.

20. The method according to claim 19, wherein the setting signal is generated by the microprocessor via the execution of a firmware program.
